(19) United States
(12) Patent Application Publication
(10) Pub. No.: US 2024/0387572 A1
(43) Pub. Date: Nov. 21, 2024

(54) PHOTOELECTRIC CONVERSION DEVICE, PHOTOELECTRIC CONVERSION SYSTEM, AND MOVING BODY

(71) Applicant: CANON KABUSHIKI KAISHA, Tokyo (JP)

(72) Inventor: DAIKI SHIRAHIGE, KANAGAWA (JP)

(21) Appl. No.: 18/663,921

(22) Filed: May 14, 2024

(30) Foreign Application Priority Data
May 19, 2023 (JP) 2023-083368

(51) Int. Cl. H01L 27/146

(52) U.S. Cl. CPC H01L 27/1461; H01L 27/14636; H01L 27/1465

(57) ABSTRACT

A photoelectric conversion device includes a first semiconductor unit that is arranged on a light incident surface side, and a second semiconductor unit that is arranged on a side opposite to the light incident surface side with respect to the first semiconductor unit and includes a photoelectric conversion unit containing germanium. The first semiconductor unit has a multiplication unit that performs an avalanche multiplication of electric charges generated at the photoelectric conversion unit. In a plan view, the multiplication unit overlaps the second semiconductor unit, and the area of the multiplication unit is smaller than the area of the second semiconductor unit.

### BACKGROUND

### Field of the Disclosure

The present disclosure relates to a photoelectric conversion device, a photoelectric conversion system, and a moving body.

### Description of the Related Art

There are known photoelectric conversion devices that can detect faint light of single-photon level by using avalanche multiplication. International Publication NO. 2021/215066 discusses a photoelectric conversion device that improves the sensitivity to near-infrared light by arranging a Ge absorption layer on an avalanche photodiode formed from Si, subjecting photons in the Ge absorption layer to photoelectric conversion, and performing avalanche multiplication of signal charges.

The technology discussed in International Publication No. 2021/215066 can improve the sensitivity to near-infrared light but is not sufficiently examined in noise suppression.

### SUMMARY

In view of this, at least some embodiments of the present disclosure provide a photoelectric conversion device that can suppress noise, in contrast to the configuration discussed in International Publication No. 2021/215066.

According to an aspect of the present disclosure, a photoelectric conversion device includes a first semiconductor unit that is arranged on a light incident surface side, a second semiconductor unit that is arranged on a side opposite to the light incident surface side with respect to the first semiconductor unit, and includes a photoelectric conversion unit containing germanium, and a multiplication unit that is provided at the first semiconductor unit, and configured to perform an avalanche multiplication of an electric charge generated at the photoelectric conversion unit. In a plan view, the multiplication unit overlaps the second semiconductor unit, and an area of the multiplication unit is smaller than an area of the second semiconductor unit.

Further features of various embodiments will become apparent from the following description of exemplary embodiments with reference to the attached drawings.

### BRIEF DESCRIPTION OF THE DRAWINGS

FIG. 1 is an overall view of a photoelectric conversion device according to an exemplary embodiment.

FIG. 2 is a block diagram of a substrate having a photoelectric conversion unit of the photoelectric conversion device according to the exemplary embodiment.

FIG. 3 is a block diagram of a substrate having a signal processing circuit of the photoelectric conversion device according to the exemplary embodiment.

FIG. 4 is a diagram illustrating a pixel circuit of the photoelectric conversion device according to the exemplary embodiment.

FIGS. 5A to 5C are diagrams describing driving of the pixel circuit of the photoelectric conversion device according to the exemplary embodiment.

FIG. 6 is a cross-sectional view of a pixel of a photoelectric conversion device according to a first exemplary embodiment.

FIG. 7 is a plan view of pixels of the photoelectric conversion device according to the first exemplary embodiment.

FIG. 8 is a cross-sectional view of a pixel of a photoelectric conversion device according to a second exemplary embodiment.

FIG. 9 is a cross-sectional view of a pixel of a photoelectric conversion device according to a third exemplary embodiment.

FIG. 10 is a cross-sectional view of a pixel of a photoelectric conversion device according to a fourth exemplary embodiment.

FIG. 11 is a cross-sectional view of a pixel of a photoelectric conversion device according to a fifth exemplary embodiment.

FIG. 12A is a cross-sectional view of a pixel of a photoelectric conversion device according to a sixth exemplary embodiment, and FIG. 12B is a plan view of pixels of the photoelectric conversion device according to the sixth exemplary embodiment.

FIG. 13 is a block diagram of a photoelectric conversion system according to a seventh exemplary embodiment.

FIGS. 14A and 14B are block diagrams of a photoelectric conversion system according to an eighth exemplary embodiment.

FIG. 15 is a block diagram of a photoelectric conversion system according to a ninth exemplary embodiment.

FIG. 16 is a block diagram of a photoelectric conversion system according to a tenth exemplary embodiment.

FIGS. 17A and 17B are diagrams illustrating specific examples of a photoelectric conversion system according to an eleventh exemplary embodiment.

### DESCRIPTION OF THE EMBODIMENTS

Exemplary embodiments described below are intended to embody the technical ideas of the preset disclosure and are not intended to limit every embodiment. The sizes of and positional relationships among some members illustrated in the drawings may be exaggerated for the sake of clear illustration. In the following description, some identical components may be given identical reference signs, and description thereof will be omitted.

Hereinafter, exemplary embodiments will be described in detail with reference to the drawings. In the following description, the terms indicating specific directions and positions (i.e., “upward”, “downward”, “rightward”, “leftward”, and other terms including these words) will be used as necessary. The use of these terms is intended to facilitate the understanding of the exemplary embodiments with reference to the drawings, and the technical scope of the present disclosure is not limited by the meanings of these terms.

In the following description, the anode of an avalanche photodiode (hereinafter, APD) is set to a fixed electric potential, and signals are taken out from the cathode side. Thus, a first conductivity-type semiconductor area in which electric charges of the same polarity as the signal charges are a majority carrier is the N-type semiconductor area, and a second conductivity-type semiconductor area in which electric charges of the polarity different from the signal charges are a majority carrier is the P-type semiconductor area. Some embodiments are also applicable to the case where the cathode of the APD is set to a fixed electric potential, and signals are taken out from the anode side. In this case, the first conductivity-type semiconductor area in which electric charges of the same polarity as the signal charges are a majority carrier is the P-type semiconductor area, and the second conductivity-type semiconductor area in which electric charges of the polarity different from the signal charges are a majority carrier is the N-type semiconductor area. In the following description, one node of the APD is set to a fixed electric potential, but the APD may be configured such that the potentials of both nodes vary.

If the term “impurity concentration” is simply used herein, the term means the net impurity concentration from which the impurities compensated for by reverse conductivity-type impurities are subtracted. That is, the “impurity concentration” refers to the net doping concentration. The area in which the P-type additive impurity concentration is higher than the N-type additive impurity concentration is the P-type semiconductor area. In contrast, the area in which the N-type additive impurity concentration is higher than the P-type additive impurity concentration is the N-type semiconductor area.

The term “plan view” herein refers to a plan view seen from a direction vertical to the light incidence surface of a semiconductor layer or the surface of the same opposite to the light incidence surface, which is equivalent to a two-dimensional plan view obtained by projecting an image of the constituent elements of the photoelectric conversion device onto the surface of the semiconductor layer.

The semiconductor layer has a first surface and a second surface that is opposite to the first surface. The first surface is the surface on which the main wiring structure is provided, and the second surface is the surface opposite to the surface on which the main wiring structure is provided. For example, in the back-type semiconductor layer, the light incidence surface is the second surface, and the surface opposite to the light incidence surface is the first surface. The depth direction herein refers to the direction from the first surface to the second surface of the semiconductor layer. The “first surface” may be called “front surface”, and the “second surface” may be called “back surface”. The direction from a predetermined position on the semiconductor layer to the back surface of the semiconductor layer may be expressed as “deep”. The direction from a predetermined position on the semiconductor layer to the front surface of the semiconductor layer may be expressed as “narrow”.

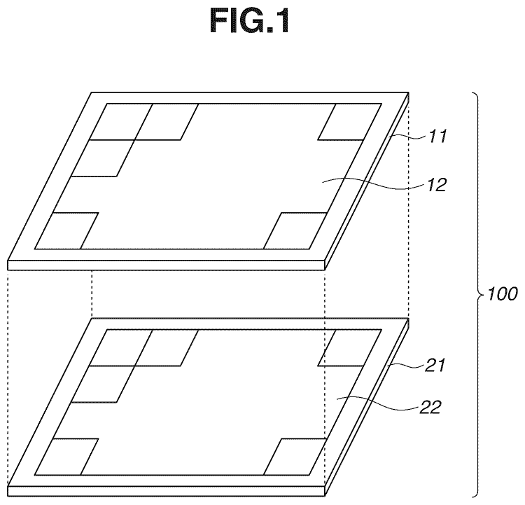

FIG. 1 is a diagram illustrating a configuration of a lamination-type photoelectric conversion device according to an example embodiment. A photoelectric conversion device 100 is formed by laminating and electrically connecting two chips, that is, a sensor chip 11 and a circuit chip 21. The chips here include a configuration in which wafers are bonded together into a chip, a configuration in which a chip is bonded onto a wafer to turn the wafer into a chip, and a configuration in which chips are bonded together.

The sensor chip 11 has a pixel area 12, and the circuit chip 21 has a circuit area 22 that has a circuit to process signals detected in the pixel area 12.

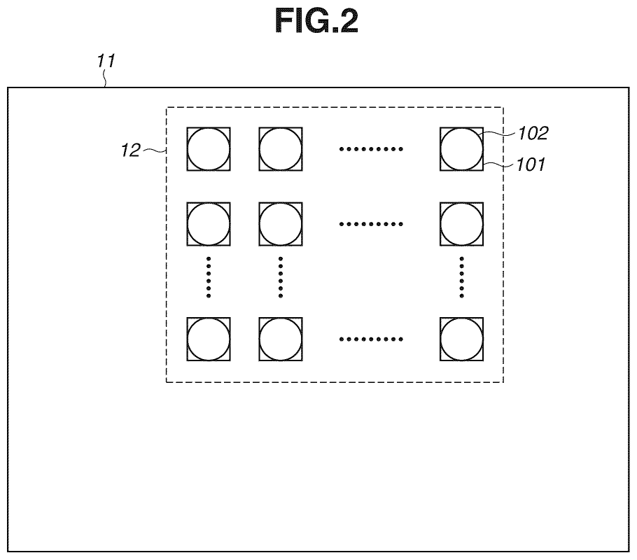

FIG. 2 is a diagram illustrating arrangement of the sensor chip 11. Pixels 101, each of which having a photoelectric conversion unit 102 including an APD, are arranged two-dimensionally to form the pixel area 12.

The pixels 101 are typically pixels for forming an image. However, in a case of using a time of flight (TOF), the pixels 101 are not necessarily required to form an image. That is, the pixels 101 may be pixels for measuring the arrival time of light and the amount of the light.

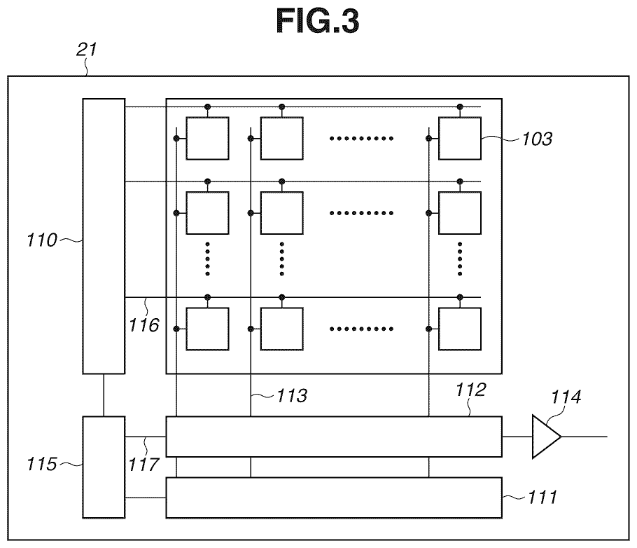

FIG. 3 is a configuration diagram of the circuit chip 21. The circuit chip 21 includes signal processing units 103 that process electric charges having undergone photoelectric conversion by the photoelectric conversion units 102 illustrated in FIG. 2, a read circuit 112, a control pulse generation unit 115, a horizontal scanning circuit unit 111, signal lines 113, and a vertical scanning circuit unit 110.

The photoelectric conversion units 102 illustrated in FIG. 2 and the signal processing units 103 illustrated in FIG. 3 are electrically connected together via connection wiring provided in the corresponding pixels.

The vertical scanning circuit unit 110 receives a control pulse supplied from the control pulse generation unit 115 and supplies the control pulse to the individual pixels. As the vertical scanning circuit unit 110, a logical circuit is used, such as a shift register or an address decoder.

The signals output from the photoelectric conversion units 102 of the pixels are processed by the corresponding signal processing units 103. The signal processing units 103 are each provided with a counter and a memory, and the memory holds digital values.

The horizontal scanning circuit unit 111 inputs control pulses for selecting the individual columns of the pixels in sequence to the signal processing units 103 in order to read signals from the memories of the pixels that hold digital signals.

In the selected column, signals are output from the signal processing units 103 of the pixels selected by the vertical scanning circuit unit 110 to the signal line 113.

The signals output to the signal line 113 are then output through the output circuit 114 to a recording unit or a signal processing unit outside the photoelectric conversion device 100.

The pixels 101 in the pixel area 12 illustrated in FIG. 2 may be arranged one-dimensionally. All the pixels 101 are not necessarily required to have the function of the signal processing unit 103, and a plurality of pixels 101 may share one signal processing unit 103 to perform signal processing in sequence.

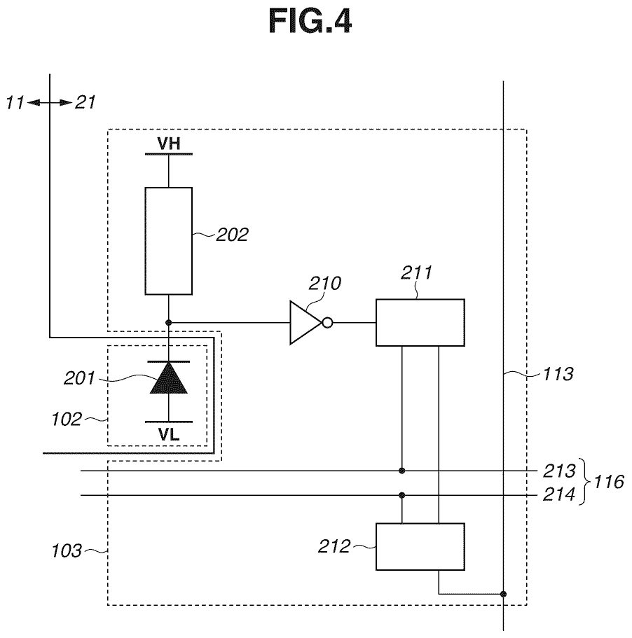

FIG. 4 illustrates an example of blocks including a pixel circuit in a pixel. Referring to FIG. 2, the photoelectric conversion unit 102 having an APD 201 is provided on the sensor chip 11, and other members are provided on the circuit chip 21.

The APD 201 generates an electric charge pair in accordance with incident light by photoelectric conversion. A voltage VL (first voltage) is supplied to the anode of the APD 201. A voltage VH (second voltage) higher than the voltage VL to the anode is supplied to the cathode of the APD 201. A reverse bias voltage is supplied to the anode and the cathode such that the APD 201 performs an avalanche multiplication operation. When such a voltage is supplied, the electric charges generated by the incident light cause an avalanche multiplication to generate avalanche current. In the case where the reverse bias voltage is supplied, operation modes used are the following: a Geiger mode in which the APD is operated with potential differences in the anode and the cathode that are larger than the breakdown voltage; and a linear mode in which the APD is operated with these potential differences that are near or less than the breakdown voltage. An APD operated in the Geiger mode will be referred to as a single-photon avalanche diode (SPAD). For example, the voltage VL (first voltage) may be −30 V (volts), and the voltage VH (second voltage) may be 1 V.

A quench element 202 is connected to a power source that supplies the voltage VH and the APD 201. The quench element 202 has a function of transforming a change in the avalanche current generated in the APD 201 into a voltage signal. At a time of signal multiplication by avalanche multiplication, the quench element 202 functions as a load circuit (quench circuit) and acts to suppress the voltage to be supplied to the APD 201, thereby suppressing the avalanche multiplication (quench operation). As the quench element 202, a transistor may be provided. A clock signal may also be input to the gate of this transistor to apply a reverse bias voltage on a periodic basis. In this case, when the transistor is in an on state, the reverse bias voltage is applied to the APD 201, that is, the APD 201 is charged and turned into a recharged state. When the transistor is in an off state, a predetermined reverse bias voltage is applied to the APD 201 and the transistor is not electrically conductive, and thus the APD 201 is placed on a standby state to wait for incidence of photons. Such a transistor is also treated as a quench element herein.

The signal processing unit 103 includes a waveform shaping unit 210, a counter circuit 211, and a selection circuit 212. The signal processing unit 103 herein may have any one of the waveform shaping unit 210, the counter circuit 211, and the selection circuit 212.

The waveform shaping unit 210 shapes a change in the potential of the cathode of the APD 201 obtained at the time of photon detection, and outputs a pulse signal. As the waveform shaping unit 210, an inverter circuit is used, for example. FIG. 4 illustrates an example in which one inverter is used as the waveform shaping unit 210, but a circuit with a plurality of inverters connected in series can also be used, or any other circuit having the effect of waveform shaping can be used.

The counter circuit 211 counts pulse signals output from the waveform shaping unit 210 and holds a count value. When a control pulse pRES is supplied via a drive line 213, the counter circuit 211 is reset to clear the signal held therein.

A control pulse pSEL is supplied from the vertical scanning circuit unit 110 illustrated in FIG. 1 to the selection circuit 212 via a drive line 214 illustrated in FIG. 4 (not illustrated in FIG. 3) to switch between electrical connection and disconnection of the counter circuit 211 and the signal line 113. The selection circuit 212 includes, for example, a buffer circuit for outputting signals.

A switch, such as a transistor, may be arranged between the quench element 202 and the APD 201 and between the photoelectric conversion unit 102 and the signal processing unit 103 to switch between electrical connection and disconnection. Similarly, a switch, such as a transistor, may be used to switch between the supply of the voltage VH and the supply of the voltage VL to the photoelectric conversion unit 102.

In the present exemplary embodiment, the counter circuit 211 is used. Instead of the counter circuit 211, the photoelectric conversion device 100 for acquiring a pulse detection timing may also be used by using a time-to-digital converter (hereinafter, TDC) and a memory. In this case, the generation timing of a pulse signal output from the waveform shaping unit 210 is converted into a digital signal by the TDC. In measuring the pulse signal timing, a control pulse pREF (reference signal) is supplied to the TDC via the drive line from the vertical scanning circuit unit 110 illustrated in FIG. 3. The TDC acquires a signal where the input timing of the signal output from each pixel via the waveform shaping unit 210 is regarded as a relative time with reference to the control pulse pREF, as a digital signal.

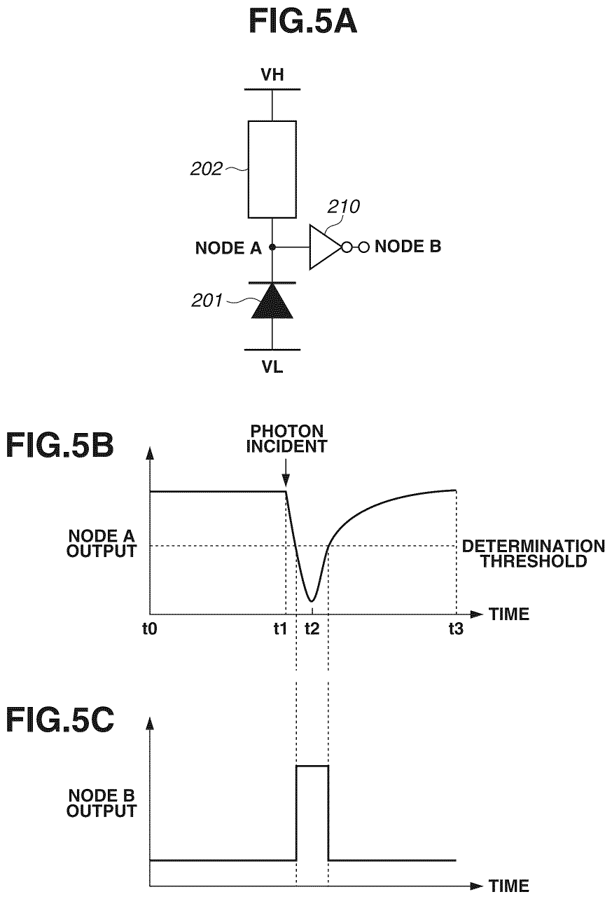

FIGS. 5A to 5C are diagrams schematically illustrating the relationship between the operation of the APD and the output signal. FIG. 5A is a diagram of the APD 201, the quench element 202, and the waveform shaping unit 210 extracted from FIG. 2. The input side of the waveform shaping unit 210 is set as node A, and the output side of the same is set as node B. FIG. 5B illustrates changes in the waveform of the node A illustrated in FIG. 5A, and FIG. 5C illustrates changes in the waveform of the node B illustrated in FIG. 5A.

During a period from time to to time t1, a potential difference VH-VL is applied to the APD 201 illustrated in FIG. 5A.

With incident photons at time t1, an avalanche multiplication current flows into the quench element 202, and the voltage of the node A drops. When the amount of the voltage drop further becomes large and the potential difference applied to the APD 201 becomes small, the avalanche multiplication of the APD 201 stops and the voltage level of the node A no longer drops from a certain value. After that, the current compensating for the voltage drop from the voltage VH flows into the node A, and at time t3, the node A is stabilized at the original potential level.

At this time, the part of the output waveform in the node A exceeding a determination threshold is shaped by the waveform shaping unit 210 and output from the node B as a signal.

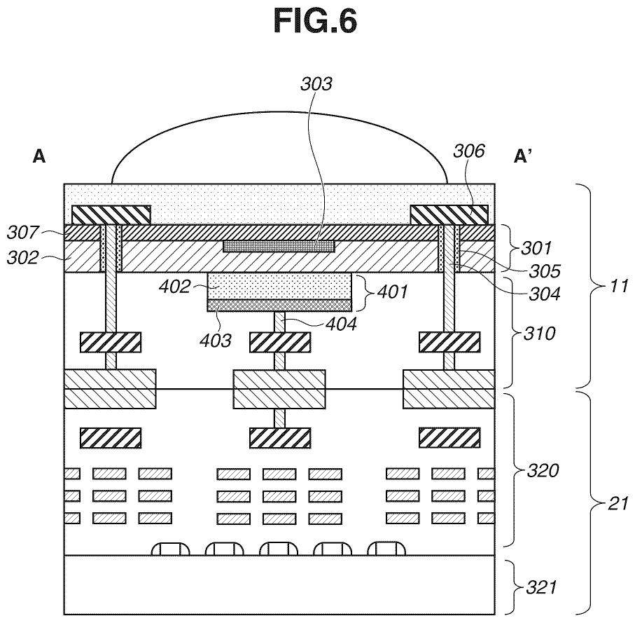

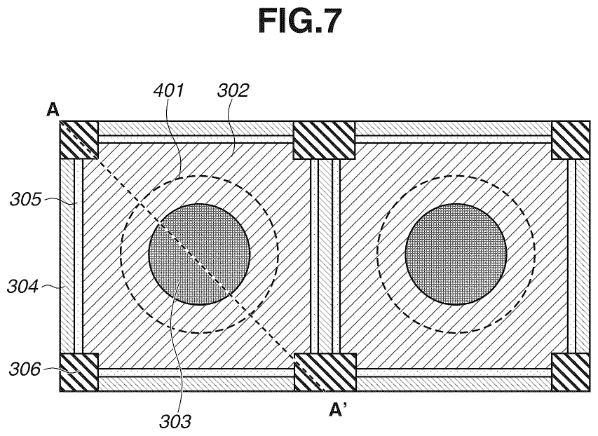

A photoelectric conversion device according to a first exemplary embodiment will now be described with reference to FIG. 6, which is a cross-sectional view, and FIG. 7, which is a plan view.

Referring to FIG. 6, the sensor chip 11 having the photoelectric conversion unit 102 and the circuit chip 21 having the signal processing unit 103 are laminated to each other.

On the upper side (front surface side) of a first semiconductor unit 301 (semiconductor layer 301 that is a silicon layer) made of silicon, a second semiconductor unit 401 containing germanium is provided. The second semiconductor unit 401 is a semiconductor made of, for example, silicon and a germanium compound. The wording “made of a material A (or materials A and B)” does not means that the component is fully made of the material A (or the materials A and B) but means that the component may include impurities that are inevitable due to manufacturing processes.

On the first semiconductor unit 301, a first wiring structure 310 is provided. In contrast, a second wiring structure 320 is provided on the upper side (front surface side) of a semiconductor layer 321 included in the circuit chip 21. A metal wiring unit and an insulating unit are provided on the upper surface of the first wiring structure 310 and the upper surface of the second wiring structure 320. The metal wiring units and the insulating units on the first wiring structure 310 and the second wiring structure 320 are bonded together.

The first semiconductor unit 301 has an n-type semiconductor area 303 (first semiconductor area), an n-type semiconductor area 307 (third semiconductor area), and a semiconductor area 302 (fifth semiconductor area) that is any one of n-type, p-type, and i-type semiconductor areas. The impurity concentration of the n-type semiconductor area 303 is higher than the impurity concentration of the n-type semiconductor area 307. If the semiconductor area 302 is of the n-type, the impurity concentration of the n-type semiconductor area 303 is higher than the impurity concentration of the n-type semiconductor area 302.

The n-type semiconductor area 307 is electrically connected to cathode electrodes 306, and the voltage VL is supplied from the cathode electrodes 306 to the n-type semiconductor area 307. The voltage VL is also supplied to the n-type semiconductor area 303 via the n-type semiconductor area 307.

The voltage VL is supplied from the wiring provided in the first wiring structure 310 to the cathode electrodes 306 via through electrodes 304 provided in through holes that penetrate the semiconductor layer 301. Each through electrode 304 is formed of a metallic film (e.g., a tungsten film) excellent in light reflectivity and electrical conductivity. In order to avoid electrical conduction between through wiring 312 and the semiconductor layer 301, an insulator 305 is provided in each through hole so as to be positioned between the through electrode 304 and the semiconductor layer 301. The through electrode 304 and the insulator 305 also function as a separation part between pixels (pixel separation part). Each insulator 305 is formed of, for example, silicon oxide.

The second semiconductor unit 401 is formed of a material containing germanium (e.g., a compound of silicon and germanium (SiGe)). The second semiconductor unit 401 has an i-type or p-type semiconductor area 402 (fourth semiconductor area) and a p-type semiconductor area 403 (second semiconductor area). If the semiconductor area 402 is of the p-type, the impurity concentration of the p-type semiconductor area 403 is higher than the impurity concentration of the p-type semiconductor area 402. The i-type semiconductor layer herein refers to a non-doped (undoped) semiconductor layer. The term “non-doped (undoped)” means that a dopant for controlling the conductivity type is not doped intentionally during growth of the semiconductor layer.

The p-type semiconductor area 403 is electrically connected to an anode electrode 404, and the voltage VH is supplied from the anode electrode 404.

The semiconductor area 402 of the second semiconductor unit 401 is formed on the front surface of the first semiconductor unit 301 by, for example, epitaxial growth. If the semiconductor area 402 is of the p-type or n-type, impurities may be implanted into the semiconductor area 402 after the epitaxial growth, or the semiconductor area 402 may be formed with addition of impurities during the epitaxial growth. Although not illustrated in FIG. 6, a selective growth insulating film (mask) is provided on the front surface of the first semiconductor unit 301. This enables the selective crystalline growth of the material containing germanium at the part of the first semiconductor unit 301 without the selective growth insulating film. The material of the selective growth insulating film can be selected from among, for example, silicon oxide, silicon nitride, silicon oxynitride, and aluminum oxide. After the epitaxial growth of the material containing germanium, a step of forming a wiring structure and pasting the same to the circuit chip is executed. The execution of this step avoids the placing of the wiring structure on a thermal load at the time of crystalline growth of the material containing germanium.

FIG. 7 is a plan view of FIG. 6, which is a plan view from the back surface side of the semiconductor layer 301. The cross-sectional view taken along line A-A′ in FIG. 7 corresponds to FIG. 6. Referring to FIG. 7, the n-type semiconductor area 303 (first semiconductor area) is provided to be surrounded by the semiconductor area 302 (fifth semiconductor area) that is of any one of the n-type, p-type, and i-type.

The through electrodes 304 and the insulators 305 surround the peripheries of the pixels so as to separate and partition the pixels. The cathode electrodes 306 is arranged at the four corners of each pixel.

The n-type semiconductor area 303 and the second semiconductor unit 401 are provided so as to overlap each other. The outer edge of the n-type semiconductor area 303 (first semiconductor area) indicated by a solid line is positioned inside the outer edge of the second semiconductor unit 401 indicated by a dotted line, for example, inside the p-type semiconductor area 403 (second semiconductor area).

As described above, the voltage VL is supplied to the n-type semiconductor area 303 (first semiconductor area), the voltage VH is supplied to the p-type semiconductor area 403 (second semiconductor area), and the reverse bias voltage is applied between these semiconductor areas. Thus, a depletion layer is formed in an area between the semiconductor area 303 and the semiconductor area 403, and a large potential difference is generated in the area, whereby an avalanche multiplication unit is provided to subject signal charges to avalanche multiplication.

The second semiconductor unit 401 is formed of a semiconductor containing germanium, and germanium and a compound of silicon and germanium have narrower bandgaps than silicon.

The semiconductor containing germanium is thereby high in sensitivity to light in a long-wavelength band to which silicon is low in sensitivity. The layer having the semiconductor containing germanium is thereby possible to generate signal charges corresponding to light in the long-wavelength band. The signal charges generated by the second semiconductor unit 401 flow into the multiplication unit due to a potential gradient. In the present exemplary embodiment, as described above, the outer edge of the semiconductor area 303 is positioned inside the p-type semiconductor area 403, and thus the area of the multiplication unit that performs an avalanche multiplication is smaller than the area of the second semiconductor unit 401. International Publication No. 2021/215066 discusses that the area of the first semiconductor unit formed of a silicon semiconductor is larger than the area of the second semiconductor unit containing germanium in a plan view, and that the avalanche multiplication area is formed at the first semiconductor unit. In the international publication No. 2021/215066, the area of the multiplication unit that performs an avalanche multiplication is larger than the area of the second semiconductor unit. As a result, dark current is prone to occur and the value of dark count rate (DCR) becomes large. According to the configuration of the present exemplary embodiment, in contrast, the area of the multiplication unit is smaller than the area of the second semiconductor unit, so that it is possible to suppress the occurrence of dark current and improve the value of the DCR.

A second exemplary embodiment is different from the first exemplary embodiment in that a p-type semiconductor area 501 (sixth semiconductor area) is provided.

In the case of forming a second semiconductor unit 401 that is a semiconductor containing germanium by crystalline growth on a first semiconductor unit 301 that is a silicon semiconductor, these semiconductors are different in lattice constant, and there is a possibility that a dislocation may occur due to a lattice mismatch. Thus, this dislocation may form a deep level in the bandgap that may become a generation source of dark current.

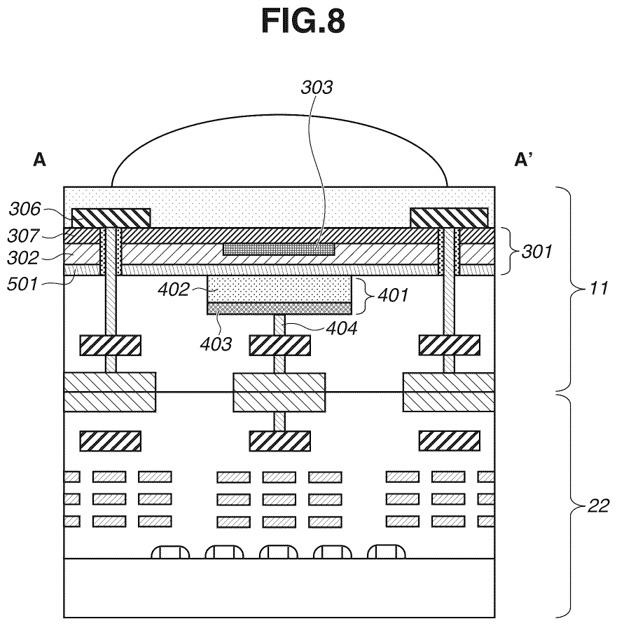

In view of this, in the second exemplary embodiment, as illustrated in FIG. 8, the p-type semiconductor area 501 (sixth semiconductor area) is formed on the first semiconductor unit 301 that is in contact with a second semiconductor unit 401. This suppresses the occurrence of dark current.

With the configuration of the present exemplary embodiment as well, the area of the multiplication unit is smaller than the area of the second semiconductor unit, so that it is possible to suppress the occurrence of dark current and improve the value of the DCR.

Besides the p-type semiconductor area 501 provided on the front surface side of the first semiconductor unit 301, a p-type semiconductor area (not illustrated) may be provided on the back surface side of the first semiconductor unit 301. This configuration also makes it possible to prevent the occurrence of dark current on the back surface side.

A third exemplary embodiment is different from the second exemplary embodiment in that a p-type semiconductor area 502 (seventh semiconductor area) is provided.

On the interface between silicon constituting a first semiconductor unit 301 and an insulator 305 of a pixel separation part, a defect level may be created to generate dark current.

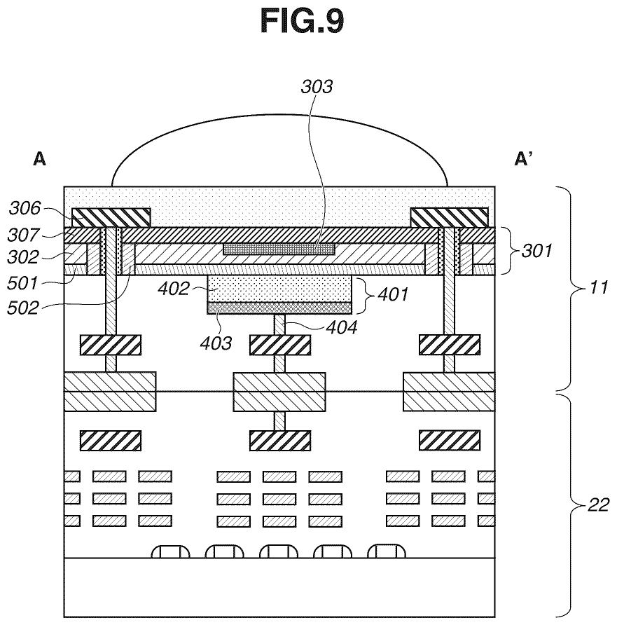

In the third exemplary embodiment, as illustrated in FIG. 9, the p-type semiconductor area 502 is provided on the first semiconductor unit 301 that is adjacent to the insulator 305 constituting the pixel separation part. This suppresses dark current that may occur on the interface with the pixel separation part.

The p-type semiconductor area 502 can move signal charges toward the multiplication unit by suppressing the movement of the signal charges in the direction toward the adjacent pixel. This makes it possible to suppress reduction in photon detection efficiency (PDE) even in the configuration in which the area of the multiplication unit of the n-type semiconductor area 303 is made small.

A fourth exemplary embodiment is different from the third exemplary embodiment in that a p-type semiconductor area 503 (eighth semiconductor area) is provided.

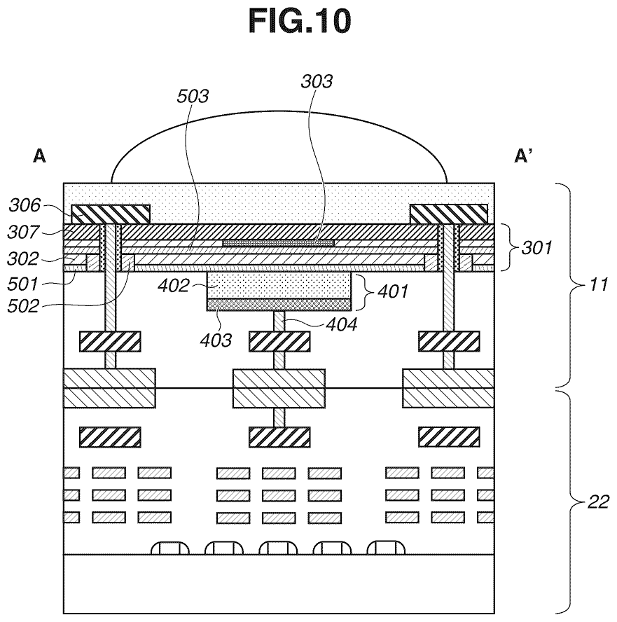

Specifically, as illustrated in FIG. 10, the p-type semiconductor area 503 (eighth semiconductor area) is provided between an n-type semiconductor area 303 (first semiconductor area) and a second semiconductor unit 401. The p-type semiconductor area 503 is electrically connected to a p-type semiconductor area 502 (seventh semiconductor area) and a p-type semiconductor area 501 (sixth semiconductor area).

The p-type semiconductor area 503 (eighth semiconductor area) is arranged at a position adjacent to the n-type semiconductor area 303 (first semiconductor area), and thereby a steeper p-n junction is formed immediately under the n-type semiconductor area 303 (first semiconductor area). This makes it possible to apply a potential used for avalanche multiplication under low applied voltage as compared to the case of the third exemplary embodiment, thereby achieving a reduction in power consumption.

With the configuration of the fourth exemplary embodiment as well, the area of the multiplication unit is smaller than the area of the second semiconductor unit, so that it is possible to suppress the occurrence of dark current and improve the value of the DCR.

A fifth exemplary embodiment is different from the first exemplary embodiment in the configuration of a second semiconductor unit 401.

At the time of epitaxial growth of a semiconductor area 402 of the second semiconductor unit 401 on the surface of a first semiconductor unit 301, a dislocation may occur due to a lattice mismatch between the silicon material and the material containing germanium.

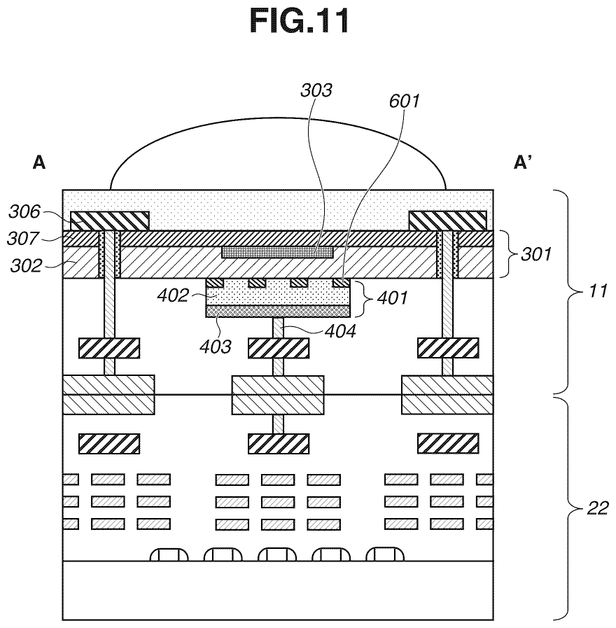

In view of this, a selective growth insulation film 601 is provided in the fifth exemplary embodiment, as illustrated in FIG. 11. Accordingly, the material containing germanium that grows from the part without the selective growth insulation film 601 makes crystalline growth in the lateral direction, for example, so that the dislocation is terminated on the selective growth insulation film 601. This makes it possible to form a second semiconductor unit 401 with high quality and suppress the occurrence of dark current that might be generated at the second semiconductor unit 401.

The material of the selective growth insulation film 601 can be selected from among, for example, silicon oxide, silicon nitride, silicon oxynitride, and aluminum oxide.

The material containing germanium makes crystalline growth from the part without the selective growth insulation film 601, and thus takes columnar shapes in cross-sectional view. The i-type or p-type semiconductor area 402 (fourth semiconductor area) may therefore be expressed as having columnar parts.

A sixth exemplary embodiment is different from the above-described exemplary embodiments in that, instead of the n-type semiconductor area 303 (first semiconductor area), a p-type semiconductor area 504 (ninth semiconductor area) is provided.

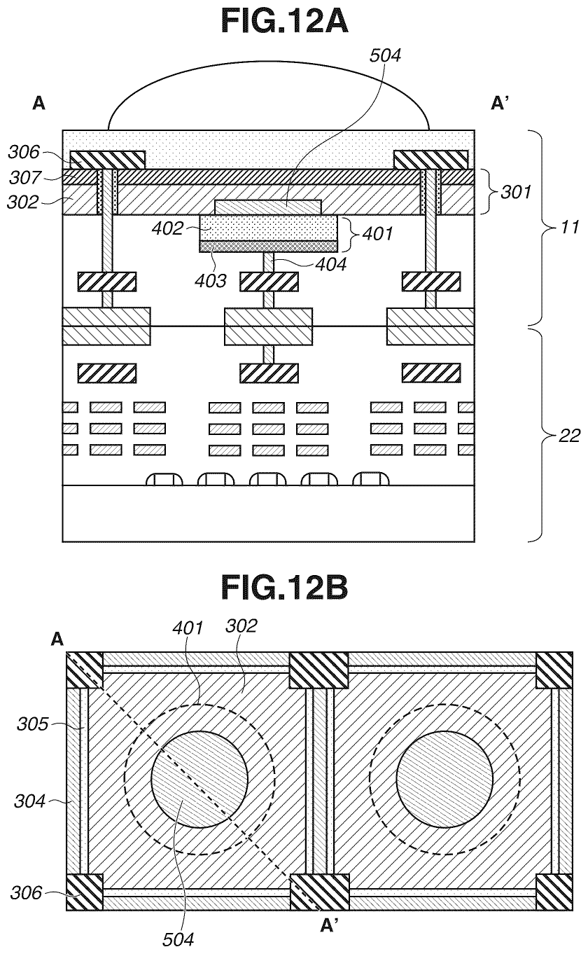

As illustrated in FIG. 12A, cathode electrodes 306 are electrically connected to an n-type semiconductor area 307 (third semiconductor area) according to the sixth exemplary embodiment. In addition, an anode electrode 404 is electrically connected to the p-type semiconductor area 504 (ninth semiconductor area) via a second semiconductor unit 401. A depletion layer is thus formed between the p-type semiconductor area 504 (ninth semiconductor area) and the n-type semiconductor area 307 (third semiconductor area). On the depletion layer, a multiplication unit that subjects signal charges to avalanche multiplication is provided.

As illustrated in FIG. 12B, the p-type semiconductor area 504 and the second semiconductor unit 401 are provided so as to overlap each other. The outer edge of the p-type semiconductor area 504 (ninth semiconductor area) indicated by a solid line is positioned inside the outer edge of the second semiconductor unit 401 indicated by a dotted line, for example, inside the p-type semiconductor area 403 (second semiconductor area).

In the present sixth embodiment, as illustrated in FIG. 12B, the outer edge of the semiconductor area 504 is positioned inside the p-type semiconductor area 403, and thus the area of the multiplication unit that performs an avalanche multiplication is smaller than the area of the second semiconductor unit 401. International Publication No. 2021/215066 discusses that the area of the first semiconductor unit made of a silicon semiconductor is larger than the area of the second semiconductor unit containing germanium in a plan view, and the avalanche multiplication area is formed at the first semiconductor unit. According to International Publication No. 2021/215066, the area of the multiplication unit that performs an avalanche multiplication is thus larger than the area of the second semiconductor unit. As a result, dark current is prone to occur and the value of the dark count rate (DCR) becomes large. On the other hand, the area of the multiplication unit is smaller than the area of the second semiconductor unit according to the configuration of the present exemplary embodiment, so that it is possible to suppress the occurrence of dark current and improve the value of the DCR.

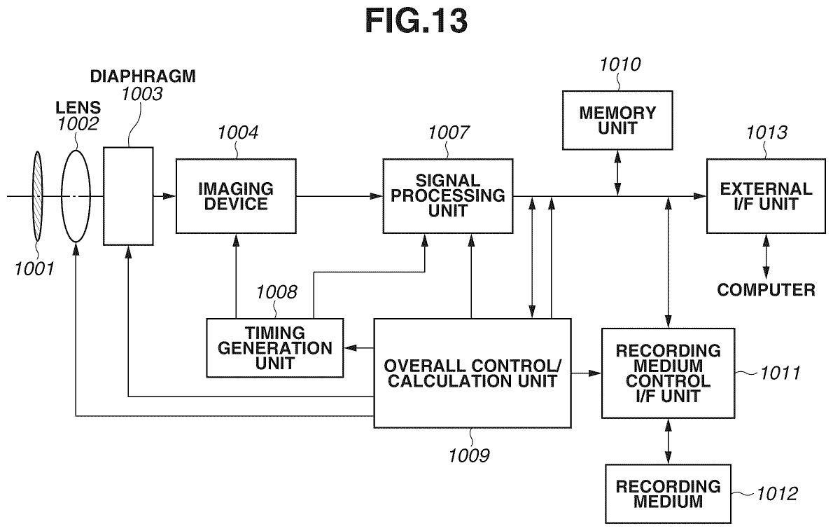

A photoelectric conversion system according to a seventh exemplary embodiment will be described with reference to FIG. 13. FIG. 13 is a block diagram illustrating a schematic configuration of the photoelectric conversion system according to the present exemplary embodiment.

The photoelectric conversion devices according to the exemplary embodiments described above are applicable to various photoelectric conversion systems. Examples of the applicable photoelectric conversion systems include digital still cameras, digital camcorders, monitoring cameras, copying machines, facsimiles, mobile phones, in-vehicle cameras, observation satellites, and others.

Camera modules including an optical system, such as lens and an imaging device, are also included in the category of photoelectric conversion systems. FIG. 13 is a block diagram of a digital still camera as one of these examples.

The photoelectric conversion system illustrated in FIG. 13 includes an imaging device 1004 that is an example of a photoelectric conversion device and a lens 1002 that forms an optical image of a subject on the imaging device 1004. The photoelectric conversion system further includes a diaphragm 1003 that makes variable the amount of light passing through the lens 1002 and a barrier 1001 for protection of the lens 1002. The lens 1002 and the diaphragm 1003 constitute an optical system that collects light on the imaging device 1004. The imaging device 1004 is the photoelectric conversion device according to any of the above-described exemplary embodiments, which converts the optical image formed by the lens 1002 into one or more electrical signals.

The photoelectric conversion system includes a signal processing unit 1007 as an image generation unit that generates an image by processing an output signal from the imaging device 1004. The signal processing unit 1007 performs, as necessary, operations of performing various corrections and compression, and outputting the resultant image data. The signal processing unit 1007 may be formed on the semiconductor layer on which the imaging device 1004 is provided or may be formed on a semiconductor layer different from that on which the imaging device 1004 is provided. The imaging device 1004 and the signal processing unit 1007 may be formed on an identical semiconductor layer.

The photoelectric conversion system further includes a memory unit 1010 that temporarily stores image data and an external interface unit (external I/F unit) 1013 for communicating with external computers and others. The photoelectric conversion system further includes a recording medium 1012, such as a semiconductor memory for recording or reading image data, and a recording medium control interface unit (recording medium control I/F unit) 1011 for recording data into or reading data from the recording medium 1012. The recording medium 1012 may be built in the photoelectric conversion system or may be detachably attached to the photoelectric conversion system.

The photoelectric conversion system further includes an overall control/calculation unit 1009 that performs various calculations and controls the overall digital still camera, and a timing generation unit 1008 that outputs various timing signals to the imaging device 1004 and the signal processing unit 1007. Since the timing signals and the like may be externally input, the photoelectric conversion system may include at least the imaging device 1004 and the signal processing unit 1007 that processes output signals from the imaging device 1004.

The imaging device 1004 outputs an image signal to the signal processing unit 1007. The signal processing unit 1007 performs predetermined signal processing on the image signal output from the imaging device 1004, and outputs the image data. The signal processing unit 1007 uses the image signal to generate an image.

According to the present exemplary embodiment, it is possible to implement, as described above, a photoelectric conversion system to which the photoelectric conversion device (imaging device) according to any of the above-described exemplary embodiments is applied.

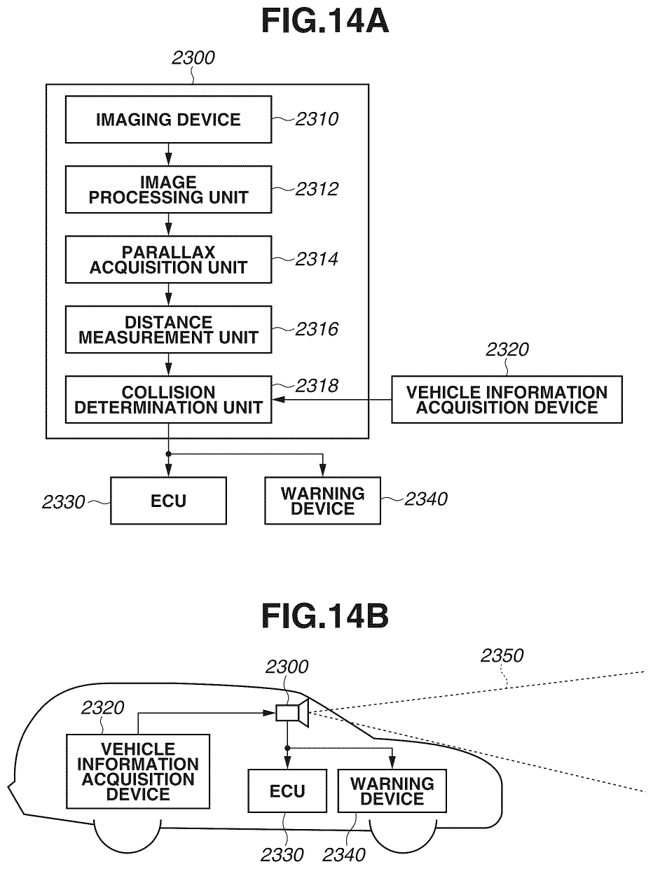

A photoelectric conversion system and a moving body according to an eighth exemplary embodiment will now be described with reference to FIGS. 14A and 14B. FIGS. 14A and 14B are diagrams illustrating configurations of the photoelectric conversion system and the moving body according to the present exemplary embodiment.

FIG. 14A illustrates an example of photoelectric conversion system related to an in-vehicle camera. A photoelectric conversion system 2300 has an imaging device 2310. The imaging device 2310 is the photoelectric conversion device according to any of the exemplary embodiments described above. The photoelectric conversion system 2300 includes an image processing unit 2312 that performs image processing on a plurality of pieces of image data acquired by the imaging device 2310. The photoelectric conversion system 2300 also includes a parallax acquisition unit 2314 that calculates a parallax (phase difference between parallax images) from the plurality of pieces of image data acquired by the photoelectric conversion system 2300. The photoelectric conversion system 2300 further includes a distance measurement unit 2316 that calculates a distance to a target object based on the calculated parallax and a collision determination unit 2318 that determines whether there is a possibility of a collision based on the calculated distance. The parallax acquisition unit 2314 and the distance measurement unit 2316 are examples of a distance information acquisition unit that acquires distance information to the target object. That is, the parallax acquisition unit 2314 and the distance measurement unit 2316 may acquire the distance information using not only the phase difference but also time-of-flight (ToF) techniques. The collision determination unit 2318 may use any of these pieces of distance information to determine the possibility of a collision. The distance information acquisition unit may be implemented by dedicatedly designed hardware or may be implemented by a software module. The distance information acquisition unit may also be implemented by a field programmable gate array (FPGA) or an application specific integrated circuit (ASIC) or the like or may be implemented by a combination of them.

The photoelectric conversion system 2300 is connected to a vehicle information acquisition device 2320 and can acquire vehicle information, such as vehicle speed, yaw rate, and steering angle. The photoelectric conversion system 2300 is also connected to an engine control unit (ECU) 2330 that is a control device (control unit) that outputs a control signal to generate a braking force to the vehicle, based on the result of the determination by the collision determination unit 2318. The photoelectric conversion system 2300 is also connected to a warning device 2340 that issues a warning to the driver based on the result of the determination by the collision determination unit 2318. For example, if the result of the determination by the collision determination unit 2318 shows that there is a high possibility of a collision, the ECU 2330 controls the vehicle to avoid a collision or reduce collision damage by applying the brake, releasing the pedal, or suppressing the engine output.

The warning device 2340 issues a warning to the user by sounding an alarm, displaying warning information on the screen of a car navigation system or the like, applying vibration to the seat belt or the steering wheel, or the like.

In the present exemplary embodiment, the surroundings of the vehicle, for example, the area ahead of or behind the vehicle is imaged by the photoelectric conversion system 2300. FIG. 14B illustrates a photoelectric conversion system in the case of imaging the area (image sensing area 2350) ahead of the vehicle. The vehicle information acquisition device 2320 sends an instruction to the photoelectric conversion system 2300 or the imaging device 2310. This configuration further improves the accuracy of distance measurement.

Described above is an example of controlling the vehicle so as not to collide with another vehicle. However, this configuration is also applicable to a control for automatically driving the vehicle so as to follow another vehicle and a control for automatically driving the vehicle so as not to run off the driving lane. The photoelectric conversion system is not limited to vehicles such as automobiles, and is also applicable to moving bodies (moving devices), such as marine vessels, aircraft, and industrial robots. In addition, the photoelectric conversion system is not limited to moving bodies and is applicable to a wide variety of devices that utilize object recognition, such as the Intelligence Transport System (ITS).

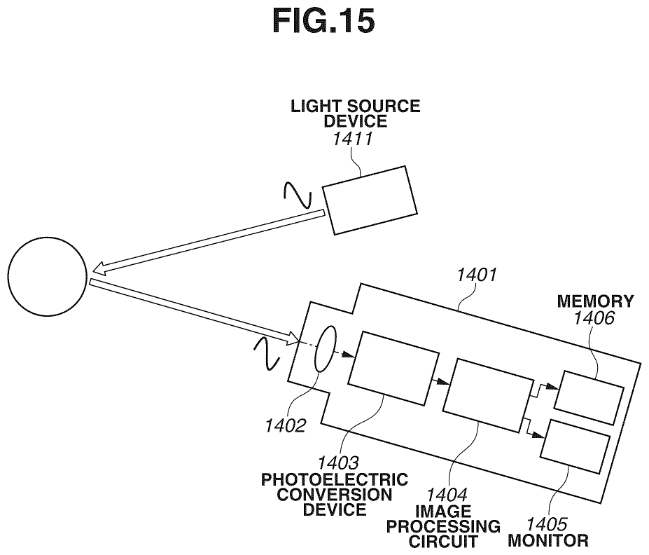

A photoelectric conversion system according to a ninth exemplary embodiment will now be described with reference to FIG. 15. FIG. 15 is a block diagram illustrating a configuration example of a distance image sensor that is a photoelectric conversion system.

As illustrated in FIG. 15, a distance image sensor 1401 includes an optical system 1402, a photoelectric conversion device 1403, an image processing circuit 1404, a monitor 1405, and a memory 1406. When a light source device 1411 projects light toward a subject, the distance image sensor 1401 receives light reflected by the surface of the subject (modulated light or pulse light), to thereby acquire a distance image in accordance with the distance to the subject.

The optical system 1402 has one or more lenses and guides image light (incident light) from the subject to the photoelectric conversion device 1403 to form an image on the light-receiving surface (sensor unit) of the photoelectric conversion device 1403.

As the photoelectric conversion device 1403, the photoelectric conversion device according to any of the exemplary embodiments described above is applied. The distance is determined from the light-receiving signal output from the photoelectric conversion device 1403, and a distance signal indicating the distance is supplied to the image processing circuit 1404.

The image processing circuit 1404 performs image processing based on the distance signal supplied from the photoelectric conversion device 1403 to create a distance image. The distance image (image data) obtained by the image processing is supplied to and displayed on the monitor 1405 or is supplied to and stored (recorded) in the memory 1406.

Applying the above-described photoelectric conversion device to the thus configured distance image sensor 1401 makes it possible to acquire an accurate distance image along with improvement in the characteristics of the pixels.

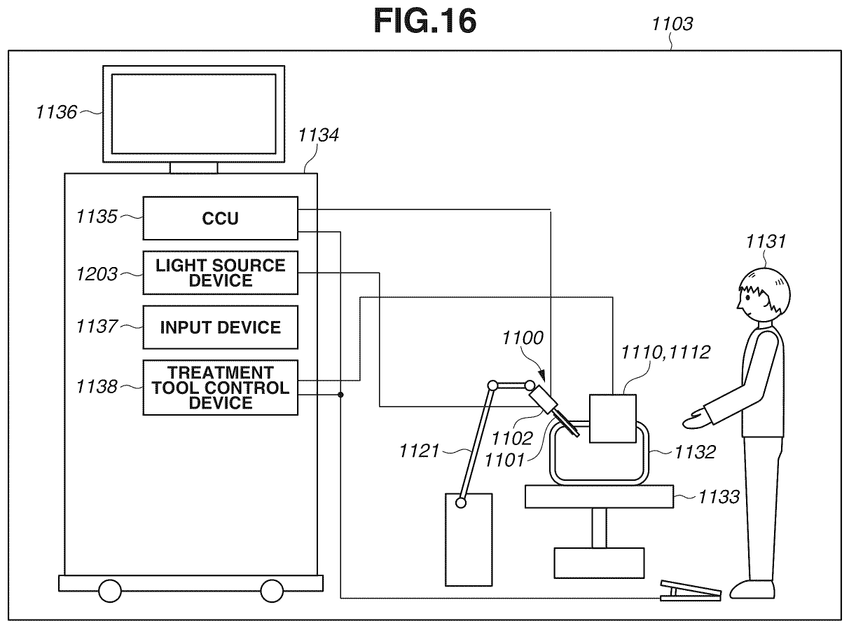

A photoelectric conversion system according to a tenth exemplary embodiment will now be described with reference to FIG. 16. FIG. 16 is a diagram illustrating an example of a schematic configuration of an endoscopic surgery system that is the photoelectric conversion system according to the present exemplary embodiment.

FIG. 16 illustrates the state in which an operator (doctor) 1131 uses an endoscopic surgery system 1103 to perform surgery on a patient 1132 on a patient bed 1133. As illustrated in the drawing, the endoscopic surgery system 1103 includes an endoscope 1100, a surgery tool 1110, and a cart 1134 on which various devices for endoscopic surgery are placed.

The endoscope 1100 includes a lens tube 1101 that is inserted into the body cavity of the patient 1132 by a predetermined length and a camera head 1102 that is connected to the base end of the lens tube 1101. In the illustrated example, the endoscope 1100 is configured as a rigid scope having a rigid lens tube 1101. Also, the endoscope 1100 may be configured as a flexible scope having a flexible lens tube.

The leading end of the lens tube 1101 has an opening into which an objective lens is fitted. The endoscope 1100 is connected to a light source device 1203. The light generated by the light source device 1203 is guided by a light guide extended in the lens tube 1101 to the leading end of the lens tube, and the light is emitted through the objective lens toward the observation target in the body cavity of the patient 1132. The endoscope 1100 may be a direct-viewing scope, a perspective-viewing scope, or a side-viewing scope.

The camera head 1102 internally includes an optical system and a photoelectric conversion device. The reflection light (observation light) from the observation target is collected by the optical system to the photoelectric conversion device. The photoelectric conversion device subjects the observation light to photoelectric conversion, to thereby generate an electric signal corresponding to the observation light, that is, an image signal corresponding to the observation image. As the photoelectric conversion device, the photoelectric conversion device according to any of the exemplary embodiments described above can be used. The image signal is transmitted as raw data to a camera control unit (CCU) 1135.

The CCU 1135, including a central processing unit (CPU) and a graphics processing unit (GPU), performs overall control of operations of the endoscope 1100 and a display device 1136. The CCU 1135 further receives an image signal from the camera head 1102 and performs various kinds of image processing on the image signal for displaying an image based on the image signal, such as development processing (de-mosaic processing), for example.

The display device 1136 displays the image based on the image signal having undergone the image processing by the CCU 1135, under the control of the CCU 1135.

The light source device 1203 includes a light source, such as a light emitting diode (LED), for example, and supplies irradiation light to the endoscope 1100 at the time of imaging the surgery site and the like.

An input device 1137 is an input interface for the endoscopic surgery system 1103. The user can input various kinds of information and instructions via the input device 1137 to the endoscopic surgery system 1103.

A treatment tool control device 1138 controls the driving of an energy treatment tool 1112 for cauterization and incision of tissue or sealing of blood vessels.

The light source device 1203 that supplies irradiation light to the endoscope 1100 at the time of imaging the surgery site includes a white light source having an LED, a laser light source, or a combination of them, for example. In the case where the white light source is formed from a combination of red, green, and blue (RGB) laser light sources, the output intensity and output timing of the light of each color (wavelength) can be controlled with high accuracy, so that the white balance of the captured image can be adjusted in the light source device 1203. In this case, the observation target may be irradiated with laser beams from the RGB laser light sources in a time-division manner, and the driving of the imaging element in the camera head 1102 may be controlled in synchronization with the irradiation timings, so that the images corresponding to the colors of RGB can be captured in a time-division manner. When using this method, it is possible to obtain a color image without providing color filters in the imaging element.

The driving of the light source device 1203 may also be controlled such that the intensity of the output light is changed at predetermined intervals. The driving of the imaging element in the camera head 1102 is controlled in synchronization with the timings of changes in the intensity of the light to acquire images in a time-division manner, and then the images are combined into an image with a high dynamic range without underexposure or overexposure.

The light source device 1203 may be made capable of supplying light in a predetermined wavelength band corresponding to special light observation. In the special light observation, the dependence of body tissue on wavelength in light absorption is utilized, for example. Specifically, the light in a narrower band than the irradiation light (i.e., white light) for use in normal observation is emitted to capture the image of predetermined tissue, such as a blood vessel in a superficial portion of a mucous membrane, with high contrast.

Alternatively, in the special light observation, fluorescence observation may be performed to obtain an image of fluorescence generated by emission of excitation light. In the fluorescence observation, it is possible to irradiate body tissue with excitation light and observe the fluorescence from the body tissue, or locally injecting a reagent such as indocyanine green (ICG) into body tissue and irradiate the body tissue with excitation light corresponding to the fluorescence wavelength of the reagent to obtain a fluorescent image. The light source device 1203 can be configured to supply the narrow-band light and/or the excitation light corresponding to the special light observation.

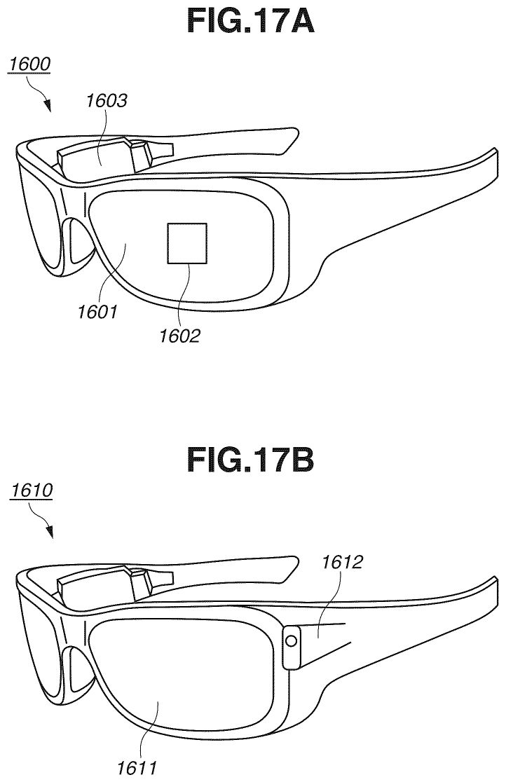

A photoelectric conversion system according to an eleventh exemplary embodiment will now be described with reference to FIGS. 17A and 17B. FIG. 17A is a diagram illustrating an example of a configuration of eyeglasses 1600 (smart glasses) that are a photoelectric conversion system.

The eyeglasses 1600 includes a photoelectric conversion device 1602. The photoelectric conversion device 1602 is the photoelectric conversion device according to any one of the first to sixth exemplary embodiments described above. A display device including a light-emitting device, such as an organic light emitting diode (OLED) or an LED, may be provided on the back surface side of a lens 1601. One or more photoelectric conversion devices 1602 may be provided. A plurality of types of photoelectric conversion devices may also be used in combination. The arrangement position of the photoelectric conversion device 1602 is not limited to that illustrated in FIG. 17A.

The eyeglasses 1600 further include a control device 1603. The control device 1603 functions as a power source that supplies electric power to the photoelectric conversion device 1602 and the display device described above. The control device 1603 also controls the operations of the photoelectric conversion device 1602 and the display device. The lens 1601 has an optical system for collecting light on the photoelectric conversion device 1602.

FIG. 17B illustrates eyeglasses 1610 (smart glasses) according to one application example. The eyeglasses 1610 have a control device 1612. The control device 1612 is equipped with a photoelectric conversion device equivalent to the photoelectric conversion device 1602 and a display device. A lens 1611 includes the photoelectric conversion device in the control device 1612 and an optical system for projecting the light emitted from the display device. An image is projected onto the lens 1611. The control device 1612 functions as a power source that supplies electric power to the photoelectric conversion device and the display device, and also controls the operations of the photoelectric conversion device and the display device. The control device may include a line-of-sight detection unit that detects the wearer's line of sight. The line of sight can be detected by using infrared rays. An infrared emission unit emits infrared light to the eyeball of the user who gazes at the displayed image. The reflection of the emitted infrared light from the eyeball is detected by the imaging unit having a light-receiving element, thereby to obtain the captured image of the eyeball. A reduction unit that reduces the light from the infrared emission unit to the display unit in a plan view is provided to reduce deterioration in the image quality.

The user's line of sight to the displayed image is detected from the captured image of the eyeball obtained by image capture with the infrared light. The detection of the line of sight using the captured image of the eyeball can be made by applying an arbitrary publicly known method. As an example, a line-of-sight detection method can be used based on a Purkinje image due to the reflection of irradiation light on the cornea.

More specifically, a line-of-sight detection process is performed based on a pupillary corneal reflex method. The line-of-sight vector indicating the direction (rotation angle) of the eyeball is calculated based on the image of the pupil and the Purkinje image seen in the captured image of the eyeball by using the pupillary corneal reflex method, thereby detecting the user's line of sight.

The display device according to the present exemplary embodiment may include a photoelectric conversion device having a light-receiving element and may control the displayed image on the display device based on the user's line-of-sight information from the photoelectric conversion device.

Specifically, the display device determines a first field-of-view area on which the user gazes and a second field-of-view area other than the first field-of-view area, based on the line-of-sight information. The first field-of-view area and the second field-of-view area may be determined by the control device in the display device or may be obtained by receiving those determined by an external control device. In the display area of the display device, the display resolution in the first field-of-view area may be made higher than the display resolution of the second field-of-view area. That is, the resolution of the second field-of-view area may be made lower than the resolution of the first field-of-view area.

The display area may have a first display area and a second display area that is different from the first display area. Out of the first display area and the second display area, the area with a higher priority may be determined based on the line-of-sight information. The first field-of-view area and the second field-of-view area may be determined by the control device in the display device or may be obtained by receiving those determined by an external control device. The resolution of the area with a high priority may be made higher than the resolution of the area other than the area with the high priority. That is, the resolution of the area with a relatively low priority may be made lower.

The first field-of-view area and the area with a high priority may be determined by using artificial intelligence (AI). The AI may be a model that is configured to estimate the angle formed by the line of sight and the distance to a target object in the line of sight, from the image of the eyeball, by using training data of the image of the eyeball and the viewing direction in which the eyeball was actually looking. An AI program may be included in the display device, may be included in the photoelectric conversion device, or may be included in an external device. In the case where the AI program is included in an external device, the AI program is transferred to the display device via communication.

In the case of performing display control based on recognition detection, smart glasses further having a photoelectric conversion device that captures an image of the outside can be preferably applied. The smart glasses can display captured external information in real time.

The exemplary embodiments described above can be altered as appropriate without departing from the technical ideas. The exemplary embodiments of the present disclosure also include an example in which some components of any of the exemplary embodiments are added to another exemplary embodiment and an example in which some components of any of the exemplary embodiments are replaced with some components of another exemplary embodiment.

According to the present disclosure, it is possible to provide a photoelectric conversion device that can suppress noise, in contrast to the configuration discussed in International Publication No. 2021/215066.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2023-083368, which was filed on May 19, 2023 and which is hereby incorporated by reference herein in its entirety.

What is claimed is:

1. A photoelectric conversion device comprising:
a first semiconductor unit that is arranged on a light incident surface side;
a second semiconductor unit that is arranged on a side opposite to the light incident surface side with respect to the first semiconductor unit, and includes a photoelectric conversion unit containing germanium; and
a multiplication unit that is provided at the first semiconductor unit and that is configured to perform an avalanche multiplication of an electric charge generated at the photoelectric conversion unit,
wherein, in a plan view, the multiplication unit overlaps the second semiconductor unit, and an area of the multiplication unit is smaller than an area of the second semiconductor unit.

2. The photoelectric conversion device according to claim 1,
wherein the first semiconductor unit has a first semiconductor area of a first conductivity type,
wherein the second semiconductor unit has a second semiconductor area of a second conductivity type that is a conductivity type opposite to the first conductivity type,
wherein the multiplication unit is formed in an area between the first semiconductor area and the second semiconductor area, and
wherein, in a plan view, an outer edge of the first semiconductor area is positioned inside of an outer edge of the second semiconductor area.

3. The photoelectric conversion device according to claim 2,
wherein the first semiconductor unit has a silicon layer, and
wherein wiring that supplies a voltage to the first semiconductor area penetrates the silicon layer.

4. The photoelectric conversion device according to claim 3, further comprising an insulator between the wiring that supplies a voltage to the first semiconductor area and the silicon layer, and
wherein a seventh semiconductor area of the second conductivity type is provided on the silicon layer adjacent to the insulator.

5. The photoelectric conversion device according to claim 4,
wherein an eighth semiconductor area of the second conductivity type is provided between the first semiconductor area and the second semiconductor unit, and
wherein the eighth semiconductor area and the seventh semiconductor area are electrically connected together.

6. The photoelectric conversion device according to claim 2,
wherein the first semiconductor unit has a third semiconductor area of the first conductivity type closer to the light incidence surface side than the first semiconductor area, and
wherein impurity concentration of the first semiconductor area is higher than impurity concentration of the third semiconductor area.

7. The photoelectric conversion device according to claim 6,
wherein the first semiconductor unit has a silicon layer,
wherein wiring that supplies a voltage to the third semiconductor area penetrates the silicon layer, and
wherein the wiring supplies a voltage to the first semiconductor area via the third semiconductor area.

8. The photoelectric conversion device according to claim 2,
wherein the second semiconductor unit is of an i-type or the second conductivity type, and includes a fourth semiconductor area that has an impurity concentration lower than an impurity concentration of the second semiconductor area, and
wherein the fourth semiconductor area is provided between the first semiconductor unit and the second semiconductor area.

9. The photoelectric conversion device according to claim 2,
wherein the first semiconductor unit includes a fifth semiconductor area that is of an i-type or the first conductivity type and has an impurity concentration lower than an impurity concentration of the first semiconductor area, or is of the second conductivity type and has an impurity concentration lower than an impurity concentration of the second semiconductor area, and
wherein the fifth semiconductor area is provided between the first semiconductor area and the second semiconductor unit.

10. The photoelectric conversion device according to claim 9, wherein the first semiconductor unit has a sixth semiconductor area of the second conductivity type between the fifth semiconductor area and the second semiconductor unit.

11. The photoelectric conversion device according to claim 10,
wherein the first semiconductor unit has a silicon layer,
wherein an insulator is provided between wiring that supplies a voltage to the first semiconductor area and the silicon layer,
wherein a seventh semiconductor area of the second conductivity type is provided on the silicon layer adjacent to the insulator,
wherein an eighth semiconductor area of the second conductivity type is provided between the first semiconductor area and the second semiconductor unit,
wherein the sixth semiconductor area and the seventh semiconductor area are electrically connected together, and
wherein the seventh semiconductor area and the eighth semiconductor area are electrically connected together.

12. The photoelectric conversion device according to claim 1, wherein an insulation film is provided between the first semiconductor unit and the second semiconductor unit.

13. The photoelectric conversion device according to claim 12, wherein the insulation film is a mask for use in crystalline growth of the second semiconductor unit.

14. The photoelectric conversion device according to claim 1,
wherein the first semiconductor unit has a third semiconductor area of a first conductivity type and a ninth semiconductor area of a second conductivity type that is a conductivity type opposite to the first conductivity type,
wherein the second semiconductor unit has a second semiconductor area of the second conductivity type,
wherein the multiplication unit is formed in an area between the third semiconductor area and the ninth semiconductor area, and
wherein, in a plan view, an outer edge of the ninth semiconductor area is positioned inside of an outer edge of the second semiconductor area.

15. A photoelectric conversion system comprising:
a photoelectric conversion device; and
a signal processing unit configured to generate an image using a signal output by the photoelectric conversion device,
wherein the photoelectric conversion device includes:
a first semiconductor unit that is arranged on a light incident surface side;
a second semiconductor unit that is arranged on a side opposite to the light incident surface side with respect to the first semiconductor unit, and includes a photoelectric conversion unit containing germanium; and
a multiplication unit that is provided at the first semiconductor unit and that is configured to perform an avalanche multiplication of an electric charge generated at the photoelectric conversion unit,
wherein, in a plan view, the multiplication unit overlaps the second semiconductor unit, and an area of the multiplication unit is smaller than an area of the second semiconductor unit.

16. A movable body comprising:
a photoelectric conversion device;
one or more processors; and
one or more memories,
wherein the one or more processors and the one or more memories are configured to control movement of the movable body by using a signal output by the photoelectric conversion device, and
wherein the photoelectric conversion device includes:
a first semiconductor unit that is arranged on a light incident surface side;
a second semiconductor unit that is arranged on a side opposite to the light incident surface side with respect to the first semiconductor unit, and includes a photoelectric conversion unit containing germanium; and
a multiplication unit that is provided at the first semiconductor unit and that is configured to perform an avalanche multiplication of an electric charge generated at the photoelectric conversion unit,
wherein, in a plan view, the multiplication unit overlaps the second semiconductor unit, and an area of the multiplication unit is smaller than an area of the second semiconductor unit.
